(19) United States
(12) Patent Application Publication
(10) Pub. No.: US 2026/0032998 A1
(43) Pub. Date: Jan. 29, 2026

(54) FLEXIBLE ACTIVE REGION FOR STACKED FETS

(71) Applicant: INTERNATIONAL BUSINESS MACHINES CORPORATION, Armonk, NY (US)

(72) Inventors: James Patrick Mazza, Saratoga Springs, NY (US); Ruilong Xie, Niskayuna, NY (US); Tao Li, Slingerlands, NY (US); Min Gyu Sung, Latham, NY (US); Richard C. Johnson, Selkirk, NY (US)

(21) Appl. No.: 18/780,735

(22) Filed: Jul. 23, 2024

(51) Int. Cl. H01L 27/092; H01L 21/822; H01L 21/8238; H01L 29/06; H01L 29/417; H01L 29/423; H01L 29/66; H01L 29/775; H01L 29/786

(52) U.S. Cl. CPC H10D 84/856; H10D 30/014; H10D 30/43; H10D 30/6729; H10D 30/6735; H10D 30/6757; H10D 62/121; H10D 84/0186; H10D 84/038; H10D 88/01

(57) ABSTRACT

A semiconductor device includes a stacked transistor structure having field effect transistors on two levels. Active regions are longitudinally disposed on each of the two levels. The active regions include source/drain regions and channel regions. An active region of the active regions includes a transition region wherein longitudinal portions of the one active region are laterally offset within a same level by the transition region to provide an offset space. The offset space includes a vertical interconnect.

### BACKGROUND

The present invention generally relates to semiconductor devices and processing methods, and more particularly to stacked field effect transistors (FETs) with supporting interlayer interconnect formation.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that make it challenging to provide required performance and routing connectivity.

In particular, stacked field effect transistors (FETs) formed by epitaxial growth processes that are aligned between layers make interconnect formation difficult. Vertical interconnects between layers consume real estate, and high density devices incur difficulties in wire routing. These circumstances can lead to crosstalk or capacitance issues and, in the limit, short circuits.

### SUMMARY

In accordance with an embodiment of the present invention, a semiconductor device includes a stacked transistor structure having field effect transistors on two levels. Active regions are longitudinally disposed on each of the two levels. The active regions include source/drain regions and channel regions. An active region of the active regions includes a transition region wherein longitudinal portions of the one active region are laterally offset within a same level by the transition region to provide an offset space. The offset space includes a vertical interconnect.

In other embodiments, the transition region can be disposed within a channel region of the channel regions. The vertical interconnect can include a middle of the line contact. The vertical interconnect can include a backside contact. The longitudinal portions of the at least one active region can be laterally offset from a longitudinal portion of a different level. A plurality of transition regions can be along a same active region. A plurality of transition regions can be within active regions of a same level of the at least two levels. A plurality of transition regions can be within active regions at different levels of the at least two levels.

In accordance with another embodiment of the present invention, a semiconductor device includes a first level of field effect transistors having first active regions disposed across the first level, and a second level of field effect transistors having second active regions disposed across the second level. A transition region is disposed along at least one of the second active regions to provide an offset between the at least one active region in the second level and a corresponding active region in the first level. The transition region bending the at least one active region in the second level to provide an offset space. A vertical interconnect is formed in the offset space.

In other embodiments, the transition region can be disposed within a channel region. The vertical interconnect includes a middle of the line contact. The vertical interconnect can include a backside contact. A plurality of transition regions can be along the at least one active region. A plurality of transition regions can be within different active regions of the second level. A plurality of transition regions can be within active regions on the first level and the second level. A third level of field effect transistors can have third active regions disposed across the third level. At least one transition region can be along at least one of the third active regions.

In accordance with another embodiment of the present invention, a semiconductor device includes a first level of field effect transistors having first active regions disposed across the first level, a second level of field effect transistors having second active regions disposed across the second level and a third level of field effect transistors having third active regions disposed across the third level. A transition region is disposed along at least one of the second active regions to provide an offset between the at least one active region in the second level and a corresponding active region in an adjacent level. The transition region bends the at least one active region in the second level to provide an offset space. A vertical interconnect is disposed in the offset space.

In other embodiments, the transition region can be disposed within a channel region. The vertical interconnect can include a middle of the line contact or a backside contact.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X and Y as shown in an inset, showing gates and source and drain regions formed for a first level of a semiconductor device, in accordance with an embodiment of the present invention;

FIG. 2 shows cross-sectional views, taken at section lines X and Y as shown in the inset, showing gates and source and drain regions formed for a second level of the semiconductor device and showing transition regions in active regions in the inset, in accordance with an embodiment of the present invention;

FIG. 3 shows cross-sectional views, taken at section lines X and Y as shown in the inset, showing gates and source and drain regions formed for a third level of the semiconductor device and showing transition regions in active regions in the inset, in accordance with an embodiment of the present invention;

FIG. 4 shows cross-sectional views, taken at section lines X and Y, after an interlayer dielectric layer is patterned, middle of the line contacts formed, back end of the line structures are formed, a carrier wafer is applied and the structure is flipped to process a backside, in accordance with an embodiment of the present invention;

FIG. 5 shows cross-sectional views, taken at section lines X and Y, after the substrate has been removed to an etch stop layer, in accordance with an embodiment of the present invention;

FIG. 6 shows cross-sectional views, taken at section lines X and Y, after a backside interlayer dielectric is formed and sacrificial placeholders have been exposed by etching, in accordance with an embodiment of the present invention;

FIG. 7 shows cross-sectional views, taken at section lines X and Y, after the sacrificial placeholders are removed and replaced with backside contacts, in accordance with an embodiment of the present invention; and

FIG. 8 shows cross-sectional views, taken at section lines X and Y, after forming an interconnect layer on the backside, in accordance with an embodiment of the present invention.

### DETAILED DESCRIPTION

In accordance with embodiments of the present invention, devices and methods are described which include active regions having transition portions that provide offsets between active regions in one or more adjacent layers. In an embodiment, a stacked field effect transistor (FET) device can include two or more layers of FETs. At least one layer can include an active region with an angled or lateral transition to permit an offset between reactive region lines. The offset between levels can be employed to place interconnects for wire routing. The interconnects can bypass the level or connect to the level using the space provided by the offset or offsets.

In another embodiment, the active region can include a flexible shape (e.g., non-rectangular polygon (e.g., a rhombus or parallelogram) to provide the offset for wire routing. In particularly useful embodiments, channel regions or the active regions include a different layout angle from source/drain regions attached to the channel regions.

By providing offsets, the issue of wire routing for stacked FETs, especially more than two levels of stacked FETs can be alleviated. In this way, higher levels of stacked devices can be realized to further increase device density and permit high quality and reliable wire routing. Embodiments in accordance with the present invention can therefore make use of vertical stacking without consumption of area.

In some embodiments, a semiconductor device includes a layer of transistors stacked over another layer of transistors. At least one of the layers of transistors has a portion of its active region that that is not directly across from one side of a gate to the other. Said differently; the active region (channel region) bends through the gate. The semiconductor device can include two or more layers of devices. In an embodiment, three layers of devices are employed. Frontside contacts to source/drain regions can include two or more different depths. In an embodiment, the frontside contacts to source/drain regions can include three different depths. Backside contacts to source/drain regions can include two or more different depths. In an embodiment, the backside contacts to source/drain regions can include three different depths. The channels extending through some gates can be angled or include a lateral transition that can include non-straight paths. The active region on a first side of the gate can be laterally offset from the active region on a second side of the gate. The lateral offset can be employed in one or more layers of FETs.

In other embodiments, methods for forming a semiconductor device include forming a first layer with FETs, forming a second layer of FETs stacked on the first layer. At least one of the first layer and/or the second layer include an angled or lateral transitioning shape (e.g., an offsetting shape) such that an active region is locally shifted for one of the first or second layers relative to the other. Additional stacked layers (stacked FET layers) can be employed that have straight active regions or an active region locally shifted. Frontside contacts or backside contacts use the space created by locally shifted active regions.

While illustrative embodiments will be described in terms of nanosheet devices, embodiments of the present invention can be applied to other stacked device types including but not limited to fin devices, forksheet devices, etc.

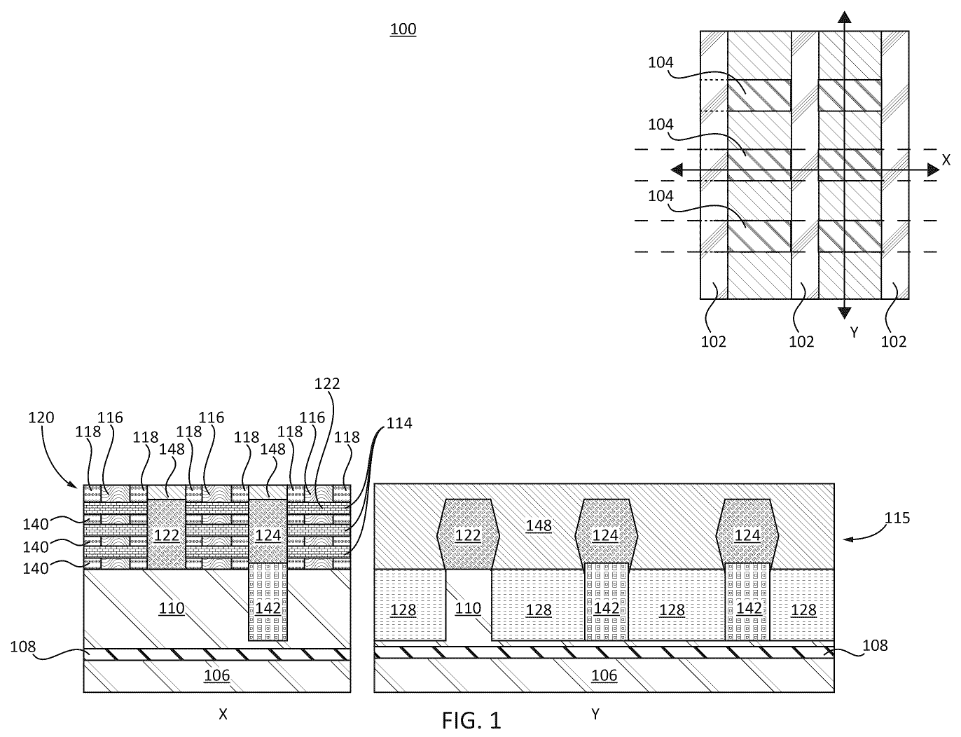

Referring now to the drawings in which like numerals represent the same or similar elements and initially to FIG. 1, devices and methods for manufacturing a stacked field effect transistor (FET) device are shown in accordance with embodiments of the present invention.

A wafer 100 includes a substrate 106 on which the stacked FET device will be fabricated. FIG. 1 depicts two orthogonal views X and Y taken at corresponding sections X and Y in inset 105. Inset 105 shows gate lines 102 and active regions lines 104 for reference. Corresponding X and Y views are depicted throughout FIGS. 1-8. Active region lines 104 represent source/drain (S/D) regions for transistor devices to be formed, and gate lines 102 are represented for such transistor devices. Transistor channels are formed along the active region lines 104 below the gate lines 102.

The substrate 106 can have a single layer or multiple layers on which a stacked FET device will be fabricated. The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In one embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

Shallow trench isolation (STI) or STI regions 128 are formed in trenches etched in the semiconductor layer 110. STI regions 128 can be formed by depositing dielectric material, such as, e.g., SiO₂, SiOₓN_{y}, SiCO or other suitable compounds. STI regions 128 can be deposited using chemical vapor deposition (CVD), although other deposition methods can be employed. The STI regions 128 can then be etched, e.g., by RIE, to a level of the semiconductor layer 110.

A layer stack 120 or stacks are applied to or formed on the semiconductor layer 110. In an embodiment, one or more nanosheets (NS) are applied to the semiconductor layer 110. In another embodiment, the layer stack 120 can be epitaxially grown using different chemistries to form layers having different properties.

In an embodiment, the layer stack 120 of the nanosheet is processed to form channel layers 114 for a first level 115 of field effect transistors (FETs) from alternating layers of the nanosheet. The other layers (semiconductor layers) of the nanosheet are removed but are employed for forming inner spacers 140. The inner spacers 140 and spacers 118 include a dielectric material, e.g., a nitride or an oxide. The inner spacers 140 can be formed by laterally etching the nanosheet layer and then filling the recess with a dielectric material. Remaining portions of the nanosheet layer that were recessed for the inner spacers 140 are removed to expose the channel layers 114.

Source/drain regions 122 and 124 can be grown using an epitaxial growth process using the channel layer 114 and/or the semiconductor layer 110 (directly or using sacrificial placeholders 142) to initiate crystal growth. Source/drain regions 124 are formed on sacrificial placeholders 142. The semiconductor layer 110 is recessed to form trenches, e.g., by RIE. Within the trenches recessed into the semiconductor layer 110, the sacrificial placeholder 142 is formed. The sacrificial placeholder 142 can be epitaxially grown in the trenches of semiconductor layer 110. The sacrificial placeholder 142 can include SiGe or other epitaxial grown material that can be selectively removed relative to the semiconductor layer 110.

The source/drain regions 122 and 124 are formed in the first level 115. The source/drain regions 122 and 124 can include Si or SiGe. In an embodiment, the source/drain regions 122, 124 can be designated as P-type or N-type devices. For example, if the source/drain regions 122 or 124 include N-type devices then the source/drain regions 122 or 124 can include Si. In another example, if the source/drain regions 122 or 124 include P-type devices then the source/drain regions 122 or 124 can include SiGe. The source/drain regions 122 or 124 can be appropriately doped during their formation. For example, the source/drain regions 122 or 124 can be doped by introducing p dopants (e.g., B, Ga, etc.) during epitaxial formation. Similarly, the source/drain regions 122 or 124 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

In some embodiments, a dummy gate material is first employed for dummy gates (not shown). The dummy gates are removed and a gate dielectric layer (not shown) is deposited to cover the channel layers 114. The gate dielectric layer can be formed by, e.g., chemical wet processes, chemical vapor deposition (CVD) and/or atomic layer deposition (ALD). Suitable examples of the gate dielectric layer can include a silicon oxide interface layer followed by a high-K dielectric oxide that can include, but is not limited to: Al₂O₃, ZrO₂, HfO₂, Ta₂O₃, TiO₂ and combinations thereof.

A bottom gate 116 is formed over the gate dielectric layer and fills spaces between the channel layers 114 that the dummy gates once occupied. This process is known as a replacement metal gate (RMG) process to form High-K Metal Gate (HKMG) structures for selectively activating FETs. The bottom gate 116 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, plasma enhanced CVD (PECVD), atomic layer deposition (ALD) or other suitable deposition process.

An interlayer dielectric (ILD) 148 is deposited over the wafer 100. The ILD 148 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 148 can be deposited using CVD, although other deposition methods can be employed. The ILD 148 is planarized, e.g., by chemical mechanical polishing (CMP).

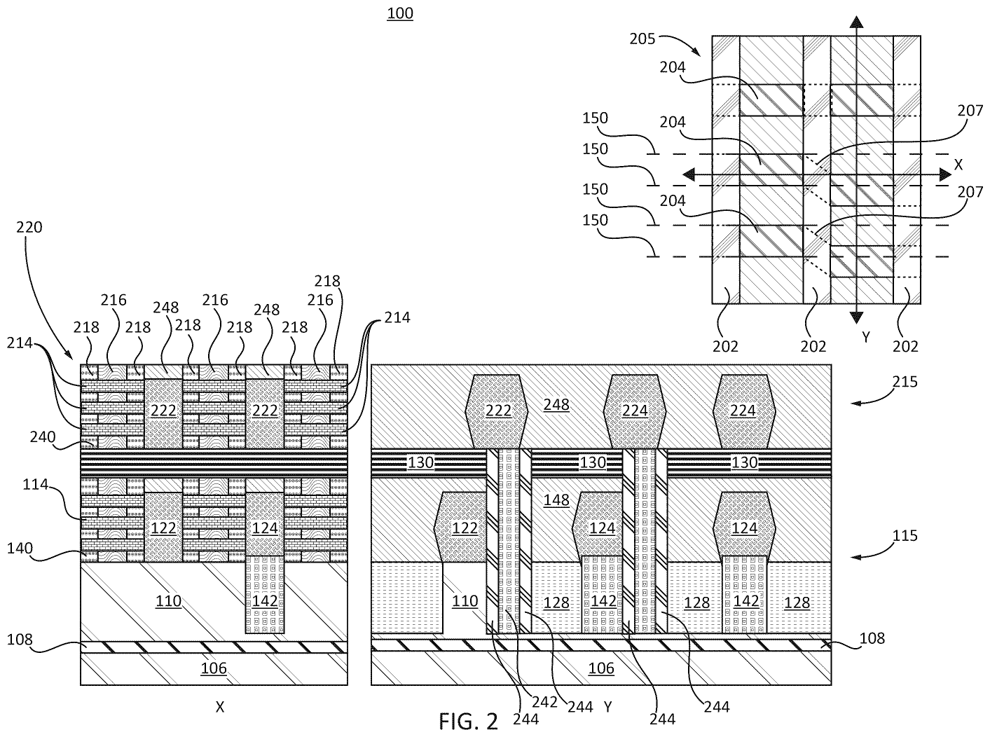

Referring to FIG. 2, a dielectric layer 130 is deposited over the wafer 100. The dielectric layer 130 can include an oxide, although other dielectric materials can be employed. The dielectric layer 130 can be deposited using CVD, ALD or any other suitable deposition methods. The dielectric layer 130 can include a bonding dielectric to which another nanosheet can be applied to process a second level 215 of FETs. The dielectric layer 130 provides a barrier between the bottom gate 116 and a gate to be formed. The dielectric layer 130 provides separation from the FETs in the first level 115 to enable continued processing for the formation of upper layers of FETs.

A layer stack 220 or stacks are applied to or formed on the first level 115. In an embodiment, one or more nanosheets (NS) are applied to the first level 115.

In an embodiment, the layer stack 220 of the nanosheet is processed to form channel layers 214 for the second level 215 of field effect transistors (FETs) from alternating layers of the nanosheet. The other layers (semiconductor layers) of the nanosheet are removed but are employed for forming inner spacers 240. The inner spacers 240 and spacers 218 include a dielectric material, e.g., a nitride or an oxide. The inner spacers 240 can be formed by laterally etching the nanosheet layer and then filling the recess with a dielectric material. Remaining portions of the nanosheet layer that were recessed for the inner spacers 240 are removed to expose the channel layers 214.

Source/drain regions 222 and 224 can be grown using an epitaxial growth process using the channel layers 214 and/or the semiconductor layer 110 (using sacrificial placeholders 242) to initiate crystal growth. Source/drain regions 222 are formed on sacrificial placeholders 242. The sacrificial placeholders 242 are formed by opening trenches through the first level 115 to expose the semiconductor layer 110. A dielectric liner 244, e.g., an oxide or nitride, is deposited (e.g., a conformal CVD or ALD) and etched, e.g., by RIE, to remove the dielectric liner 244 from horizontal surfaces and to leave the dielectric liner 244 on sidewalls of the trenches through the first level 115. The sacrificial placeholder 242 can be epitaxially grown in the trenches by initiated growth from the semiconductor layer 110. The sacrificial placeholders 242 can include SiGe or other epitaxial grown material that can be selectively removed relative to the semiconductor layer 110.

The source/drain regions 222 and 224 are formed in the second level 215. The source/drain regions 222 and 224 can include Si or SiGe. In an embodiment, the source/drain regions 222, 224 can be designated as P-type or N-type devices. For example, if the source/drain regions 222 or 224 include N-type devices then the source/drain regions 222 or 224 can include Si. In another example, if the source/drain regions 222 or 224 include P-type devices then the source/drain regions 222 or 224 can include SiGe. The source/drain regions 222 or 224 can be appropriately doped during their formation. For example, the source/drain regions 222 or 224 can be doped by introducing p dopants (e.g., B, Ga, etc.) during epitaxial formation. Similarly, the source/drain regions 222 or 224 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

In some embodiments, a dummy gate material is first employed for dummy gates (not shown). The dummy gates are removed and a gate dielectric layer (not shown) is deposited to cover the channel layers 214. The gate dielectric layer can be formed by, e.g., chemical wet processes, chemical vapor deposition (CVD) and/or atomic layer deposition (ALD). Suitable examples of the gate dielectric layer can include a silicon oxide interface layer followed by a high-K dielectric oxide that can include, but is not limited to: Al₂O₃, ZrO₂, HfO₂, Ta₂O₃, TiO₂ and combinations thereof.

A second gate 216 is formed over the gate dielectric layer and fills spaces between the channel layers 214 that the dummy gates once occupied in a RMG process to form HKMG structures for selectively activating FETs. The second gate 216 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, PECVD, ALD or other suitable deposition process.

An interlayer dielectric (ILD) 248 is deposited over the wafer 100. The ILD 248 can include any suitable material, e.g., the materials described for ILD 148. The ILD 248 can be deposited using CVD, although other deposition methods can be employed. The ILD 248 is planarized, e.g., by CMP.

The source/drain regions 222 on the second level 215 are offset from their corresponding source drain regions 122 and 124 on the first level 115. The sacrificial placeholders 242 occupy a position where source/drain contacts will be formed in later steps. The offset between the source/drain regions 222 on the second level 215 and the source drain regions 122 and 124 on the first level 115 provide sufficient space for contacts through the first level 115 to prevent short circuits and to conserve layout area. An inset 205 shows active region lines 204. Two of the active region lines 204 include angled or transition regions 207, which offset the active region lines 204 across gate lines 202. Dashed lines 150 show paths of the active region line 104 on the first level 115 to demonstrate the offsets achieved by the angled or transition regions 207.

The angled or transition regions 207 can be achieved by employing high resolution lithography imaging and patterning. The angled or transition regions 207 mean that the channels through the gates 216 are no longer square across the gates 216 and are instead angled or shaped in a way to provide an offset in which contacts can be placed without impacting areal constraints despite multiple levels (stacks) of FETs. In an embodiment, the high resolution lithography imaging can include high numerical aperture extreme ultraviolet lithography (high NA EUV) or NA EUV lithography.

High NA EUV lithography includes the use of a higher numerical aperture than EUV which allows structures with less than ten nanometers to be imaged. The numerical aperture (NA) for high NA EUV lithography is significantly larger than the previous EUV generations (e.g., NA=0.55 as opposed to NA=0.33). In this way, light from a wider angular range can be employed for imaging. This permits the printing of smaller features such as angles and transition regions 207 in chip layouts.

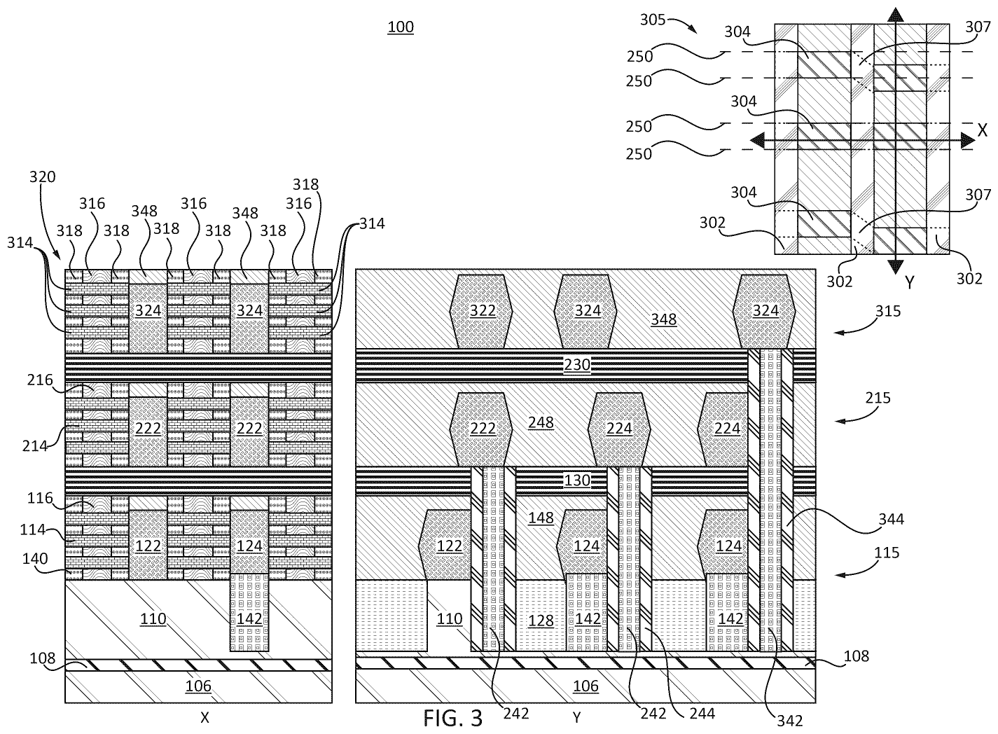

Referring to FIG. 3, a dielectric layer 230 is deposited over the wafer 100. The dielectric layer 230 can include an oxide, although other dielectric materials can be employed. The dielectric layer 230 can be deposited using CVD, ALD or any other suitable deposition methods. The dielectric layer 230 can include a bonding dielectric to which another nanosheet can be applied to process a second level 315 of FETs. The dielectric layer 230 provides a barrier between the bottom gate 216 and a gate to be formed. The dielectric layer 230 provides separation from the FETs in the second level 215 to enable continued processing for the formation of upper layers of FETs.

A layer stack 320 or stacks are applied to or formed on the second level 215. In an embodiment, one or more nanosheets (NS) are applied to the second level 215.

In an embodiment, the layer stack 320 of the nanosheet is processed to form channel layers 314 for a third level 315 of field effect transistors (FETs) from alternating layers of the nanosheet. The other layers (semiconductor layers) of the nanosheet are removed but are employed for forming inner spacers 340. The inner spacers 340 and spacers 318 include a dielectric material, e.g., a nitride or an oxide. The inner spacers 340 can be formed by laterally etching the nanosheet layer and then filling the recess with a dielectric material. Remaining portions of the nanosheet layer that were recessed for the inner spacers 340 are removed to expose the channel layers 314.

Source/drain regions 322 and 324 can be grown using an epitaxial growth process using the channel layers 314 and/or the semiconductor layer 110 (using sacrificial placeholders 342) to initiate crystal growth. Source/drain regions 324 are formed on sacrificial placeholders 342. The sacrificial placeholders 342 are formed by opening trenches through the second level 215 to expose the semiconductor layer 110. A dielectric liner 344, e.g., an oxide or nitride, is deposited (e.g., a conformal CVD or ALD) and etched, e.g., by RIE, to remove the dielectric liner 344 from horizontal surfaces and to leave the dielectric liner 344 on sidewalls of the trenches through the first level 115 and the second level 215. The sacrificial placeholder 342 can be epitaxially grown in the trenches by initiating growth from the semiconductor layer 110. The sacrificial placeholders 342 can include SiGe or other epitaxial grown material that can be selectively removed relative to the semiconductor layer 110.

The source/drain regions 322 and 324 are formed in the third level 315. The source/drain regions 322 and 324 can include Si or SiGe. In an embodiment, the source/drain regions 322, 324 can be designated as P-type or N-type devices. For example, if the source/drain regions 322 or 324 include N-type devices then the source/drain regions 322 or 324 can include Si. In another example, if the source/drain regions 322 or 324 include P-type devices then the source/drain regions 322 or 324 can include SiGe. The source/drain regions 322 or 324 can be appropriately doped during their formation. For example, the source/drain regions 322 or 324 can be doped by introducing p dopants (e.g., B, Ga, etc.) during epitaxial formation. Similarly, the source/drain regions 322 or 324 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

In some embodiments, a dummy gate material is first employed for dummy gates (not shown). The dummy gates are removed and a gate dielectric layer (not shown) is deposited to cover the channel layers 314. The gate dielectric layer can be formed by, e.g., chemical wet processes, chemical vapor deposition (CVD) and/or atomic layer deposition (ALD). Suitable examples of the gate dielectric layer can include a silicon oxide interface layer followed by a high-K dielectric oxide that can include, but is not limited to: Al₂O₃, ZrO₂, HfO₂, Ta₂O₃, TiO₂ and combinations thereof.

A third gate 316 is formed over the gate dielectric layer and fills spaces between the channel layers 314 that the dummy gates once occupied in a RMG process to form HKMG structures for selectively activating FETs. The third gate 316 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, PECVD, ALD or other suitable deposition process.

An interlayer dielectric (ILD) 348 is deposited over the wafer 100. The ILD 348 can include any suitable material, e.g., the materials described for ILD 148. The ILD 348 can be deposited using CVD, although other deposition methods can be employed. The ILD 348 is planarized, e.g., by CMP.

The source/drain regions 324 on the second level 315 can be offset from their corresponding source drain regions 222 and 224 on the second level 215. The sacrificial placeholders 342 occupy a position where source/drain contacts will be formed in later steps. The offset between the source/drain regions 324 on the third level 315 and the source drain regions 222 and 224 on the second level 215 provide sufficient space for contacts through the second level 215 and/or the first level 115 to prevent short circuits and to conserve layout area. An inset 305 shows active region lines 304. Two of the active region lines 304 include angled or transition regions 307, which offset the active region lines 304 across gate lines 302. Dashed lines 350 show paths of the active region line 204 on the second level 215 to demonstrate the offsets achieved by the angled or transition regions 307. The other angled or transition region 307 can follow a same or different angle from the angled or transition regions 207 of the second level 215. A central active region line 304 returns to a straight region from the angled or transition region 207 of the active region lines 204 just below it.

The angled or transition regions 307 can be achieved by employing high resolution lithography imaging and patterning. The angled or transition regions 307 mean that the channels through the gates 316 are no longer square across the gates 316 and are instead angled or shaped in a way to provide an offset in which contacts can be placed without impacting areal constraints despite multiple levels (stacks) of FETs. In an embodiment, the high resolution lithography imaging can include high NA EUV.

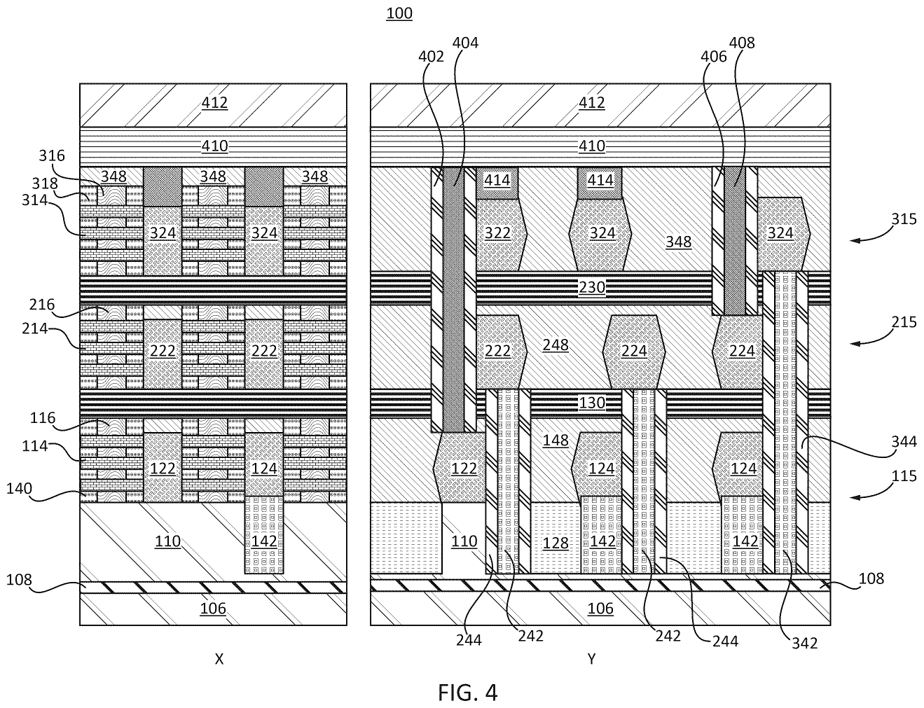

Referring to FIG. 4, middle of the line (MOL) contacts 404, 408 and 414 are formed to make connections with the source/drain regions 122, 224, 322 and 324 from a top or frontside of the wafer 100. Trenches or holes are formed in the ILD 348 and, in some cases deeper into the third level 315, the second level 215 and the first level 115. The trenches or holes expose the underlying target regions including source/drain regions 122, 224, 322 and 324. While the source/drain regions 122, 224, 322 and 324 are shown having frontside connections by MOL contacts 404, 408 and 414, it should be understood that any source/drain regions 122, 124, 222, 224, 322 and 324 can be accessed from the frontside of the wafer 100 depending on the placement of the source/drain regions 122, 124, 222, 224, 322 and 324 materials in accordance with the angled or transition regions 207, 307 that provide space for the MOL contacts 404, 408 and 414.

MOL contacts 404, 408 and 414 can be formed in different processes, which can be in accordance with a depth or level being contacted. In an embodiment, MOL contacts 404 can be formed by depositing and patterning an etch mask and then etching a trench or hole to expose the source/drain region 122 on the first level 115. In other embodiments, source/drain regions 124 can also be exposed in addition to or instead of source/drain regions 122.

A silicide liner, such as Ti, Ni, NiPt can be deposited first, then a diffusion barrier can be formed in the trench or hole. The diffusion barrier can include, e.g., TiN, TaN, or similar materials. A dielectric liner 402, e.g., an oxide or nitride, can be deposited in the trench or hole (e.g., a conformal CVD or ALD) and etched, e.g., by RIE, to remove the dielectric liner 402 from horizontal surfaces and to leave the dielectric liner 402 on sidewalls of the trench or hole. The etch exposes the source/drain region 122 on the first level 115.

A conductive fill is performed to fill the trench or hole. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the MOL contacts 404.

This process is repeated for MOL contacts 408. In an embodiment, MOL contacts 408 can be formed by depositing and patterning an etch mask and then etching a trench or hole to expose the source/drain region 224 on the second level 215. In other embodiments, source/drain regions 222 can also be exposed in addition to or instead of source/drain regions 224.

A silicide liner, such as Ti, Ni, NiPt can be deposited first, then a diffusion barrier can be formed in the trench or hole. The diffusion barrier can include, e.g., TiN, TaN, or similar materials. A dielectric liner 406, e.g., an oxide or nitride, can be deposited in the trench or hole (e.g., a conformal CVD or ALD) and etched, e.g., by RIE, to remove the dielectric liner 406 from horizontal surfaces and to leave the dielectric liner 406 on sidewalls of the trench or hole. The etch exposes the source/drain region 224 on the second level 215.

A conductive fill is performed to fill the trench or hole. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the MOL contacts 408.

MOL contacts 414 can be formed by depositing and patterning an etch mask and then etching a trench or hole to expose the source/drain regions 322, 324 on the third level 315. A silicide liner, such as Ti, Ni, NiPt can be deposited first, then a diffusion barrier can be formed in the trench or hole. The diffusion barrier can include, e.g., TiN, TaN, or similar materials.

A conductive fill is performed to fill the trench or hole. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the MOL contacts 414.

It should be understood that some of the formation processes for the MOL contacts 404, 408 and 414 can be combined. For example, a same etch mask can be employed to open all of the contacts using plugs to cover shallower openings. In addition, the conductive fill and planarizing steps can be performed concurrently for all frontside contacts.

Processing continues with the formation of back end of a line (BEOL) layer 410, which can include metal structures and dielectric layers to complete the frontside of the wafer 100 and provide electrical access to devices thereon. A carrier wafer 412 can be bonded to the BEOL layer 410. The carrier wafer 412 provides support and transportability to the wafer 100 for further processing which includes flipping the wafer 100 and removing portions of a bottom side.

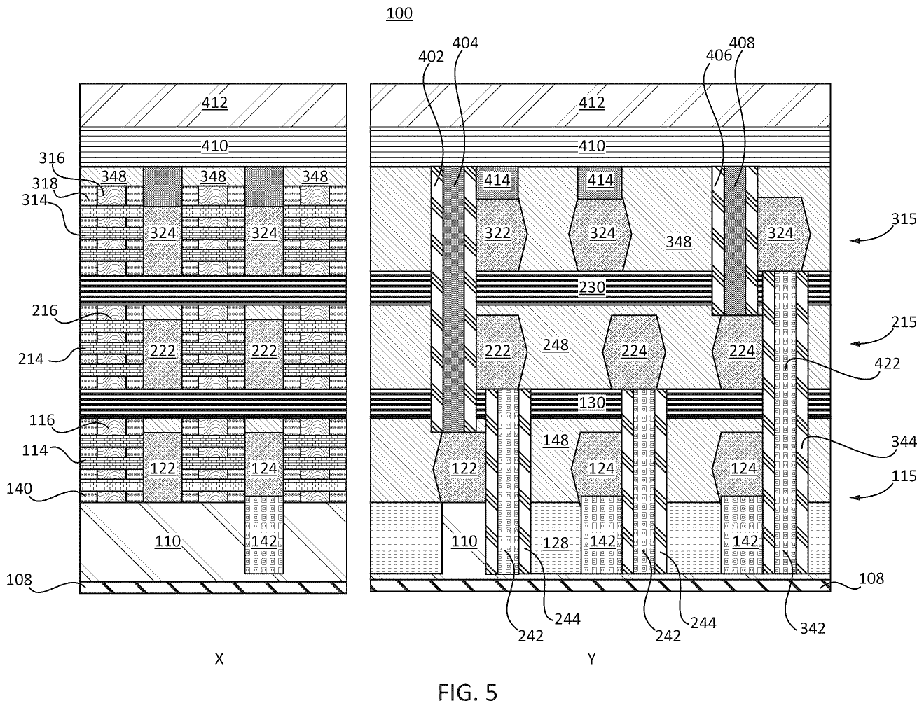

Referring to FIG. 5, to continue processing, the wafer 100 can be flipped to process features on the bottom side. However, for clarity and consistency, the wafer 100 will be shown in the FIGS. in a same orientation as previously described with continued and consistent reference to bottom/top. The substrate 106 is removed from the bottom side of the wafer 100. The substrate 106 can be removed by an etch process that stops on the etch stop layer 108.

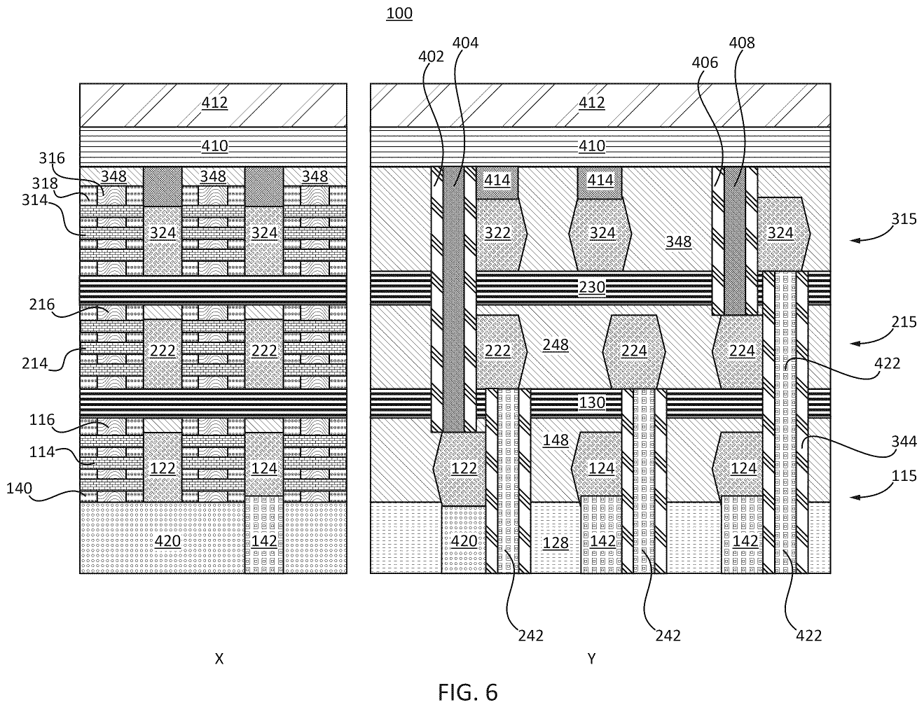

Referring to FIG. 6, the etch stop layer 108 is then removed by an etch process. In an alternate embodiment, a CMP process can be employed. With the removal of the etch stop layer 108, the semiconductor layer 110 is exposed. The semiconductor layer 110 is removed by an etch process that selectively removes the material of the semiconductor layer 110.

An interlayer dielectric (ILD) 420 is formed over the STI regions 128, the sacrificial placeholders 142, 242, 342 and bottom dielectric isolation (BDI) (not shown) below the gates 116. The ILD 420 includes a material that is selectively removeable relative to the STI regions 128 and BDI. The ILD 420 can be formed in accordance with the same of different processes and ILD 148 and can include a same or different material. The ILD 420 can be planarized, e.g., by CMP to expose the sacrificial placeholders 142, 242, 342.

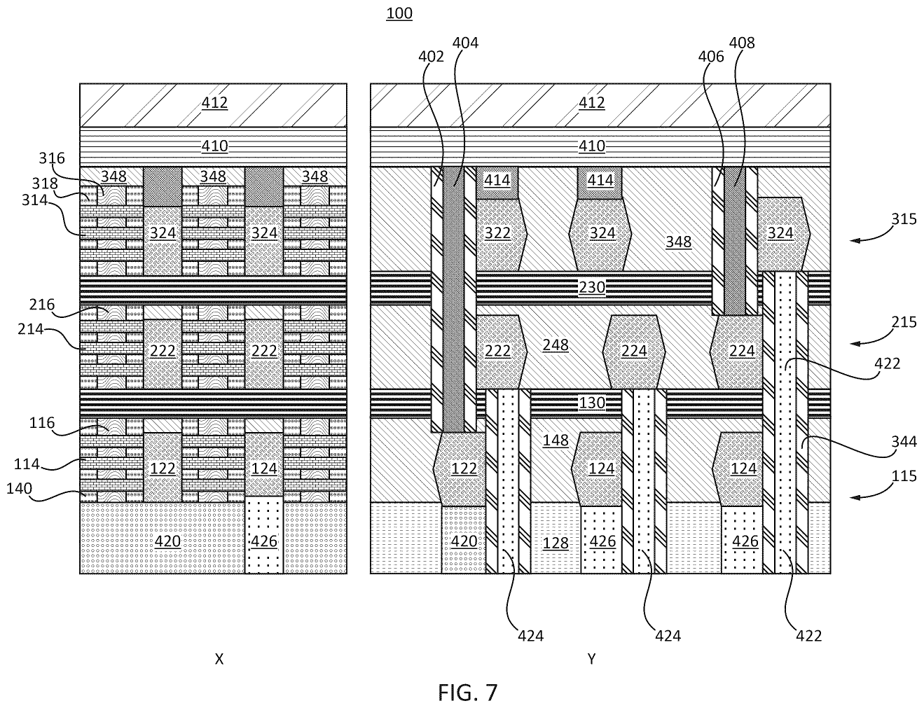

Referring to FIG. 7, backside contacts are formed to make connections with the source/drain regions at any level from the bottom side of the wafer 100. The sacrificial placeholders 142, 242, and 342 exposed from the bottom side are removed by selective etching. The etch process can include a dry etch or wet etch that selectively removes the sacrificial placeholders 142, 242, 342 to form contact openings. The corresponding source/drain regions 124, 222, 224, 324 are now exposed through the openings.

In some embodiments, a silicide liner, such as Ti, Ni, NiPt is deposited first, then a diffusion barrier can be formed in the openings left by removing the sacrificial placeholders 142, 242, 342 prior to a conductive fill. The diffusion barrier can include, e.g., TiN, TaN, or similar materials. A conductive fill is performed to fill the openings. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form backside contacts 422, 424, 426.

Backside contacts 422 extend through the first level 115 and the second level 215 to connect to source/drain regions 324 (or 322) in the third level 315. Backside contacts 424 extend through the first level 115 to connect to source/drain regions 222, 224 in the second level 215. Backside contacts 426 extend into the first level 115 to connect to source/drain regions 124 (or 122) in the first level 115.

By employing active region lines that bend or shift laterally across gates, source/drain regions can also be also shifted or offset to permit space for wire routing of vertical interconnects such as contacts among the source/drain regions. The contacts can be provided from a top side and a bottom side and can go to any level of the structure. The space provided not only supports sufficient dielectric protection for the vertical interconnects but also minimizes impact on area consumption.

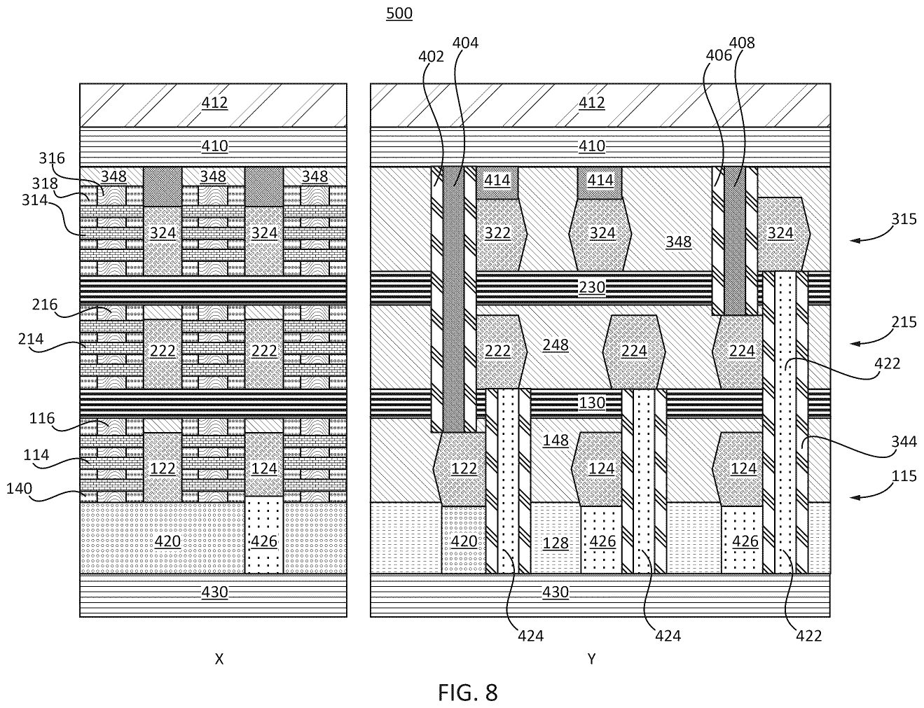

Referring to FIG. 8, processing continues with the formation of a backside interconnect layer 430, which can include metal structures and dielectric layers to complete the bottom side of a stacked FET device and provide electrical access to devices formed therein. The backside interconnect layer 430 is formed on the ILD 420, the STI regions 128 and the backside contacts 422, 424, 426.

A stacked FET device 500 is provided having FETs formed on at least two levels. While FIG. 8 shows three levels (e.g., the first level 115, the second level 215 and the third level 315), it should be understood that a greater number of levels can be formed. By providing space for vertical interconnects by angling channel regions to offset source/drain regions in portions of the stacked FET device 500, multiple levels of FETs can be provided which can significantly increase device density on a semiconductor device. The semiconductor device such as stacked FET device 500 includes a stacked transistor structure having field effect transistors on two or more levels that can be accessed from a top or front side, a bottom or backside or both.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a stacked transistor structure having field effect transistors on at least two levels;
active regions longitudinally disposed on each of the at least two levels, the active regions including source/drain regions and channel regions;
at least one active region of the active regions includes a transition region wherein longitudinal portions of the at least one active region are laterally offset within a same level by the transition region to provide an offset space; and
the offset space including a vertical interconnect.

2. The semiconductor device as recited in claim 1, wherein the transition region is disposed within a channel region of the channel regions.

3. The semiconductor device as recited in claim 1, wherein the vertical interconnect includes a middle of the line contact.

4. The semiconductor device as recited in claim 1, wherein the vertical interconnect includes a backside contact.

5. The semiconductor device as recited in claim 1, wherein the longitudinal portions of the at least one active region are laterally offset from a longitudinal portion of a different level.

6. The semiconductor device as recited in claim 1, further comprising a plurality of transition regions along a same active region.

7. The semiconductor device as recited in claim 1, further comprising a plurality of transition regions within active regions of a same level of the at least two levels.

8. The semiconductor device as recited in claim 1, further comprising a plurality of transition regions within the active regions at different levels of the at least two levels.

9. A semiconductor device, comprising:
a first level of field effect transistors having first active regions disposed across the first level;
a second level of field effect transistors having second active regions disposed across the second level;
a transition region along at least one of the second active regions to provide an offset between at least one active region in the second level and a corresponding active region in the first level, the transition region bending the at least one active region in the second level to provide an offset space; and
a vertical interconnect disposed in the offset space.

10. The semiconductor device as recited in claim 9, wherein the transition region is disposed within a channel region.

11. The semiconductor device as recited in claim 9, wherein the vertical interconnect includes a middle of the line contact.

12. The semiconductor device as recited in claim 9, wherein the vertical interconnect includes a backside contact.

13. The semiconductor device as recited in claim 9, further comprising a plurality of transition regions along the at least one active region.

14. The semiconductor device as recited in claim 9, further comprising a plurality of transition regions within different active regions of the second level.

15. The semiconductor device as recited in claim 9, further comprising a plurality of transition regions within active regions on the first level and the second level.

16. The semiconductor device as recited in claim 9, further comprising a third level of field effect transistors having third active regions disposed across the third level.

17. The semiconductor device as recited in claim 16, further comprising at least one transition region along at least one of the third active regions.

18. A semiconductor device, comprising:
a first level of field effect transistors having first active regions disposed across the first level;
a second level of field effect transistors having second active regions disposed across the second level;
a third level of field effect transistors having third active regions disposed across the third level;
a transition region along at least one of the second active regions to provide an offset between at least one active region in the second level and a corresponding active region in an adjacent level, the transition region bending the at least one active region in the second level to provide an offset space; and
a vertical interconnect disposed in the offset space.

19. The semiconductor device as recited in claim 18, wherein the transition region is disposed within a channel region.

20. The semiconductor device as recited in claim 18, wherein the vertical interconnect includes a middle of the line contact or a backside contact.
